(19) United States
(12) Patent Application Publication
(10) Pub. No.: US 2023/0402312 A1
(43) Pub. Date: Dec. 14, 2023

(54) METHOD FOR FILLING TRENCH IN SEMICONDUCTOR DEVICE

(71) Applicant: TAIWAN SEMICONDUCTOR MANUFACTURING COMPANY, LTD., Hsinchu (TW)

(72) Inventors: Kenichi SANO, Hsinchu (TW); Andrew Joseph KELLY, Hsinchu (TW); Yu-Wei LU, Hsinchu (TW); Chin-Hsiang LIN, Hsinchu (TW); Chia-Yun CHENG, Hsinchu (TW)

(73) Assignee: TAIWAN SEMICONDUCTOR MANUFACTURING COMPANY, LTD., Hsinchu (TW)

(21) Appl. No.: 17/836,463

(22) Filed: Jun. 9, 2022

(51) Int. Cl. H01L 21/762; H01L 29/06; H01L 29/423; H01L 29/786; H01L 21/02; H01L 29/66

(52) U.S. Cl. CPC H01L 21/76224; H01L 29/0665; H01L 29/42392; H01L 29/78696; H01L 21/0259; H01L 29/66545; H01L 29/66553; H01L 29/66742

(57) ABSTRACT

A method includes: applying a first solution to a semiconductor structure of a semiconductor device to form a first coating, the semiconductor structure including a feature and the trench, the first coating being formed in the trench and over the feature, the first solution containing a metal-containing solute; heating the first coating in a multi-step procedure to turn the first coating into a first film, the multi-step procedure including heating at a first temperature, followed by heating at a second temperature not lower than the first temperature; applying a second solution onto the first film to form a second coating, the second solution containing the metal-containing solute; and heating the second coating in a multi-step procedure to turn the second coating into a second film, the multi-step procedure including heating at a third temperature, followed by heating at a fourth temperature not lower than the third temperature.

### BACKGROUND

During the manufacturing of semiconductor devices, there is often a need to fill narrow gaps with suitable materials. With the continuous shrinking of critical dimensions of the semiconductor devices, it has become increasingly difficult to fill these gaps in a void-free and/or seam-free manner. Therefore, there is a need to develop methods that can better fill gaps (or trenches), especially for gaps with small dimensions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a method of filling a trench in accordance with some embodiments of this disclosure.

FIGS. 2 to 8 show intermediate steps of a method of filling a trench in accordance with some embodiments of this disclosure.

FIG. 9 is a schematic view showing multiple trenches filled with multiple films in accordance with some embodiments of this disclosure.

FIG. 10 illustrates a method of forming a semiconductor device in accordance with some embodiments of this disclosure.

FIGS. 11 to 23 show intermediate steps of a method of forming a semiconductor device in accordance with some embodiments of this disclosure.

FIG. 24 shows a test structures with multiple trenches with various dimensions being filled with a plurality of isolation structures, in accordance with some embodiments of this disclosure.

FIG. 25 is a schematic side view from FIG. 13, showing a plurality of isolation structures being filled in a plurality of trenches, in accordance with some embodiments of this disclosure.

FIG. 26 shows multiple test structures, where a plurality of isolation features are formed in spaces of various dimensions, in accordance with some embodiments of this disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. In addition, the term “source/drain portion(s)” may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

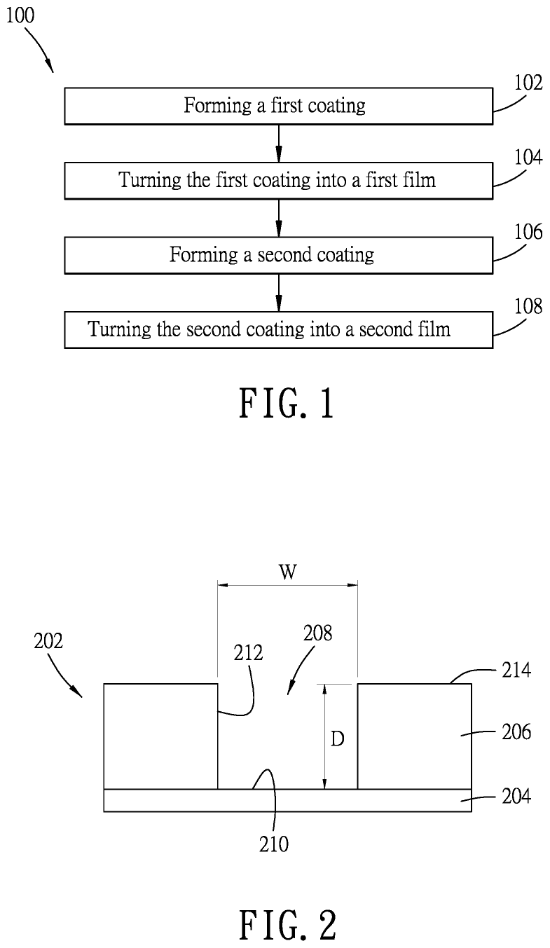

FIG. 1 illustrates a method 100 for filling a trench in accordance with some embodiments. FIGS. 2 to 7 are schematic views showing intermediate stages of the method 100 as depicted in FIG. 1. Additional steps which are not limited to those described in the method 100, can be provided before, after or during filling of the trench, and some of the steps described herein may be replaced by other steps or be eliminated. Similarly, additional features may be present, and/or features present may be replaced or eliminated in additional embodiments.

Referring to FIGS. 1 to 3, in a step 102 of the method 100, a first coating 216 is formed over a structure 202 which includes a substrate 204, a feature 206 disposed over the substrate 204, and a trench 208 formed in the feature 206. In some embodiments, a substrate surface 210 of the substrate 204 may be exposed from the trench 208. In some embodiments, a first feature surface 212 of the feature 206 may surround or may be disposed around the trench 208. That is, the trench 208 may be defined by the substrate surface 210 of the substrate 204 and the first feature surface 212 of the feature 206. In some embodiments, the feature 206 has a second feature surface 214 that is connected to the first feature surface 212 and that is disposed opposite to the substrate 204.

In some embodiments, the substrate 204 may be a semiconductor substrate, an insulating substrate, a conductive substrate, other suitable types of substrates, or any combination thereof. In some embodiments, the feature 206 may be made of a semiconductor material, an insulating material, a conductive material, other suitable types of materials, or any combination thereof.

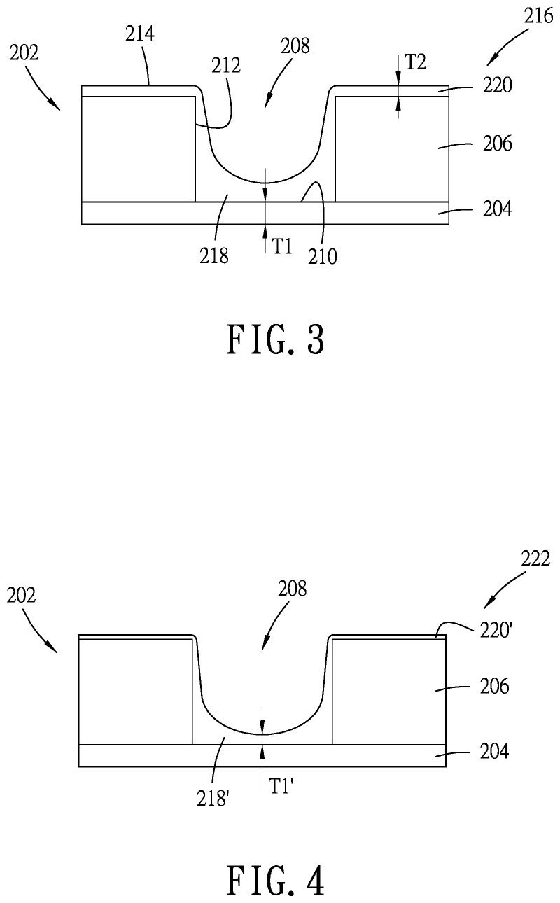

As shown in FIGS. 2 and 3, in some embodiments, the first coating 216 is formed over the feature 206 and partially fills the trench 208. In some embodiments, the first coating 216 may be formed on the substrate surface 210 of the substrate 204, the first feature surface 212 of the feature 206, and the second feature surface 214 of the feature 206. In some embodiments, the first coating 216 may be formed by coating the structure 202 with a first solution by spin coating (i.e., spin-on), drop casting, evaporative deposition, dip coating, doctor blade coating, other suitable techniques, or any combination thereof. In some embodiments, the temperature during formation of the first coating 216 may range from about 25° C. to about 60° C., but other ranges of values are also within the scope of this disclosure. In some embodiments, if the temperature during formation of the first coating 216 is too low, such as lower than about 25° C., precipitation may take place in the first solution for forming the first coating 216. In some embodiments, if the temperature during formation of the first coating 216 is too high, such as higher than about 60° C., the solvent in the first solution for forming the first coating 216 may be evaporated, leaving voids in the first coating 216 and/or adversely affecting the uniformity of the first coating 216.

Referring to FIG. 1, in a step 104 of the method 100, the first coating is turned into a first film. Referring to FIGS. 3 and 4, in some embodiments, the first coating 216 is turned into a first film 222.

In some embodiments, the first solution for forming the first coating 216 may be made by dissolving a suitable solute in a suitable solvent. In some embodiments, the solute may be a chemical compound (e.g., an ionic compound, a coordination complex, etc.), and the solvent may be a polar solvent, a non-polar solvent, other suitable types of solvent that allow the solute to dissolve or be distributed therein. In some embodiments, the solute is exemplified to be a hafnium-containing compound, e.g., hafnium tetrahalide, hafnium alkoxide, hafnium acetylacetonate (Hf(acac)₄), etc.). Examples of the hafnium tetrahalide include HfCl₄, HfI₄, etc. Examples of the hafnium alkoxide include hafnium isopropoxide, hafnium n-propoxide and hafnium n-butoxide (Hf(OnBu)₄). In some embodiments, the solvent may include propylene glycol methyl ether (PGME), propylene glycol methyl ether acetate (PGMEA), ethanol, propanol, butanol, other suitable types of solvent, or any combination thereof.

In some embodiments, the first coating 216 may be turned into the first film 222 by heating the first coating 216. In some embodiments, the heating of the first coating 216 may be carried out in a single step or in multiple steps. In some embodiments, the first coating 216 may be heated at a first temperature, followed by heating the first coating 216 at a second temperature not lower than the first temperature, thereby turning the first coating 216 into the first film 222 (i.e., the first coating 216 may be heated in an environment with increasing temperature). In some embodiments, the heating of the first coating 216 may contain four steps, including: step (1) heating at a temperature ranging from about 100° C. to about 170° C. for about 20 seconds to about 5 minutes; step (2) heating at a temperature ranging from about 170° C. to about 300° C. for about 20 seconds to about 5 minutes; step (3) heating at a temperature ranging from about 300° C. to about 550° C. for about 20 seconds to about 5 minutes; and step (4) heating at a temperature ranging from about 550° C. to about 650° C. for about 1 minute to about 10 minutes. In some embodiments, the ambient gas used for the steps (1) to (4) may be air, N₂, O₂, Ar, other suitable types of gas, or any combination thereof. In the step (1), the solvent of the first solution may be driven out (e.g., evaporated). If the heating temperature in the step (1) is too low, such as lower than about 100° C., the solvent may not be completely driven out. If the heating temperature in the step (1) is too high, such as higher than about 170° C., the solvent may be driven out too quickly, leaving voids in the first coating 216 and/or adversely affecting the uniformity of the first coating 216. If the period of heating in the step (1) is too short, such as shorter than about 20 seconds, the solvent may not be completely driven out. If the period of heating in the step (1) is too long, such as longer than about 5 minutes, the manufacturing throughput may be adversely affected. In the step (2), the metal oxide may be formed, thereby turning the first coating 216 into the first film 222 that contains the metal oxide. In some embodiments, when the solute of the first solution contains a metal coordination complex, the ligand and/or functional groups in the metal coordination complex may be formed into by-products during the heating step, and then the by-products may be removed (e.g., by evaporation), thereby obtaining the metal oxide. For example, when the metal coordination complex is Hf(OR)ₓ, in the step (2), Hf(OR)ₓ may be reacted to form HfO₂ with the generation of the by-products, such as ROH, RH, H₂O₂, CO₂, etc.. If the heating temperature in the step (2) is too low, such as lower than about 170° C., the by-products may not be completely removed. If the heating temperature in the step (2) is too high, such as higher than about 300° C., the by-products may be removed too quickly, leaving voids in the first film 222 and/or adversely affecting the uniformity of the first film 222. If the period of heating in the step (2) is too short, such as shorter than about 20 seconds, the by-products may not be completely removed. If the period of heating in the step (2) is too long, such as longer than about 5 minutes, the manufacturing throughput may be adversely affected. In the step (3), some remaining metal coordination complex after the step (2) may be turned into metal oxide. If the heating temperature in the step (3) is too low, such as lower than about 300° C., the remaining metal coordination complex may not be turned into metal oxide and the by-products may not be completely removed. If the heating temperature in the step (3) is too high, such as higher than about 550° C., the by-products may be removed too quickly, leaving voids in the first film 222 and/or adversely affecting the uniformity of the first film 222. If the period of heating in the step (3) is too short, such as shorter than about 20 seconds, the by-products may not be completely removed. If the period of heating in the step (3) is too long, such as longer than about 5 minutes, the manufacturing throughput may be adversely affected. In the step (4), the first film 222 may be heated to crystalize. If the heating temperature in the step (4) is too low, such as lower than about 550° C., the first film 222 may not crystalize. If the heating temperature in the step (4) is too high, such as higher than about 650° C., nearby elements (e.g., epitaxial structures) may be adversely affected by the high temperature. If the period of heating in the step (4) is too short, such as shorter than about 1 minute, the first film 222 may not crystalize. If the period of heating in the step (4) is too long, such as longer than about 10 minutes, the manufacturing throughput may be adversely affected.

In some embodiments, the use of a diluted solution (i.e., the diluted first solution) and heating the first coating 216 in multiple steps to remove the by-products, the first film 222 may be formed to be a continuous layer (e.g., a layer without voids and/or seams).

In some embodiments, after the step (4), a final annealing step may be applied to the first film 222 so the first film 222 may further crystalize and/or more completely crystalize. In some embodiments, the final annealing step may be carried out by heating (e.g., annealing, rapid thermal annealing (RTA), etc.) in nitrogen or other suitable types of gas at a temperature ranging from about 700° C. to about 950° C. for a period ranging from about 10 seconds to about 120 seconds, from about 10 seconds to about 20 seconds, from about 20 seconds to about 30 seconds, from about 30 seconds to about 40 seconds, from about 40 seconds to about 50 seconds, from about 50 seconds to about 60 seconds, from about 60 seconds to about 70 seconds, from about 70 seconds to about 80 seconds, from about 80 seconds to about 90 seconds, from about 90 seconds to about 100 seconds, from about 100 seconds to about 110 seconds, from about 110 seconds to about 120 seconds, or the temperature may be in other suitable ranges. In some embodiments, if the temperature of the final annealing step is too low, such as lower than about 700° C., the first film 222 may not further crystalize and/or more completely crystalize. In some embodiments, if the temperature of the final annealing step is too high, such as higher than about 950° C., the nearby elements may be adversely affected by the high temperature. In some embodiments, if the period of heating of the final annealing step is too short, such as shorter than about 10 seconds, the first film 222 may not further crystalize and/or more completely crystalize. In some embodiments, if the period of heating of the final annealing step is too long, such as longer than about 120 seconds, the manufacturing throughput may be adversely affected.

In some embodiments, the first solution for forming the first coating 216 may have a concentration ranging from about 0.00001 mol % to about 20 mol %, but other ranges of values are also within the scope of this disclosure. In other words, the first solution may be a diluted solution with concentration in the abovementioned range. In some embodiments, if the concentration of the first solution is too low, such as lower than about 0.00001 mol %, the first coating 216 may not be formed. In some embodiments, if the concentration of the first solution is too high, such as higher than about 20 mol %, the first coating 216 and/or the first film 222 may experience large shrinking, resulting in voids in the first film 222.

In some embodiments, the first solution may be applied over the feature 206 by a suitable coater to have a field thickness ranging from about 0.1 nm to about 50 nm, but other ranges of values are also within the scope of this disclosure. In some embodiments, if the field thickness is too small, such as smaller than about 0.1 nm, it indicates that the concentration of the first solution may be too low. In some embodiments, if the field thickness is too large, such as greater than about 50 nm, it indicates that the concentration of the first solution may be too high.

In some embodiments, when the first coating 216 is completely turned into the first film 222 after the step (2) of heating, the step (3) of heating may be omitted. In some embodiments, when the first film 222 crystalizes or an amorphous first film 222 is desirable, the step (4) of heating and/or the final annealing step may be omitted. In some embodiments, crystallized films may have fixed properties (e.g., dielectric value, etch resistivity, etc.), and amorphous films may have superior adhesion between films or to the feature 206.

Referring to FIG. 3, in some embodiments, the first coating 216 has a fill portion 218 that is formed in the trench 208 and covers the substrate surface 210 of the substrate 204 (see FIG. 2), and a cover portion 220 (which may be referred to as overburden) that is formed on the second feature surface 214 of the feature 206 (see FIG. 2). In some embodiments, the fill portion 218 of the first coating 216 has a thickness (T1) that is measured at a center of the trench 208, and the cover portion 220 of the first coating 216 has a thickness (T2), where T2 is smaller than about one tenth of T1. In some embodiments, if T2 is not smaller than one tenth of T1, the concentration of the first solution for forming the first coating 216 may be too large. Referring to FIG. 4, in some embodiments, the first film 222 formed from the first coating 216 may have a first fill portion 218′ that is formed from the fill portion 218 of the first coating 216 and that is formed in the trench 208, and that covers the substrate surface 210 of the substrate 204 (see FIG. 2), and a first cover portion 220′ that if formed from the cover portion 220 of the first coating 216 and that is formed on the second feature surface 214 of the feature 206 (see FIG. 2). In some embodiments, the first fill portion 218′ of the first film 222 has a thickness (T1′) measured at the center of the trench 208. In some embodiments, the first fill portion 218′ of the first film 222 shrinks, and has a shrinkage compared to the fill portion 218 of the first coating 216 that is less than 30%. That is, T1′ is greater than about seven tenths of T1. In some embodiments, if the shrinkage of the first film 222 is too large, such as greater than about 30%, voids may be formed in a resulting filling feature 234 (see FIG. 8).

In some embodiments, during each of the steps (1) to (4) of heating or after the step (4) of heating, a UV light treatment may be applied to the first coating 216 and/or the first film 222. In some embodiments, the UV light treatment may aid the removal of the by-products and/or crystallization of the first film 222, and may aid adhesion of a subsequently formed film to the first film 222. In some embodiments, the UV light treatment may use a UV light having a wavelength ranging from about 120 nm to about 220 nm (e.g., a 152 nm UV light), but other ranges of values are also within the scope of this disclosure. In some embodiments, if the wavelength of the UV light is too short, such as shorter than about 120 nm, the UV light may be easily absorbed by the first coating 216 and/or the first film 222, and may not reach deeper into the first coating 216 and/or the first film 222 (i.e., poor light penetration). In some embodiments, if the wavelength of the UV light is too long, such as longer than about 220 nm, the energy of the UV light may be too low to decompose the by-products and/or allow the first film 222 to crystallize. In some embodiments, the UV light may have an energy ranging from about 50 mJ to about 500 mJ, but other ranges of values are also within the scope of this disclosure. In some embodiments, if the energy of the UV light is too low, such as lower than about 50 mJ, the by-products may not be decomposed and the first film 222 may not crystallize. In some embodiments, if the energy of the UV light is too high, such as lower than about 500 mJ, the nearby elements may be adversely affected by the high energy UV light. In some embodiments, the temperature during the UV light treatment may be controlled within a range from about 25° C. to about 600° C., from about 25° C. to about 100° C., from about 100° C. to about 200° C., from about 200° C. to about 300° C., from about 300° C. to about 400° C., from about 400° C. to about 500° C., from about 500° C. to about 600° C., or the temperature may be in other suitable ranges. In some embodiments, if the temperature is controlled to be too low, such as lower than about 25° C., a cooling system may be needed for cooling to such a temperature, which may consume more energy. In some embodiments, if the temperature is controlled to be too high, such as higher than about 600° C., the nearby elements may be adversely affected by the high temperature. In some embodiments, the processing time of the UV light treatment may range from about 20 seconds to about 10 minutes, but other ranges of values are also within the scope of this disclosure. In some embodiments, if the processing time is too short, such as shorter than about 20 seconds, the ligand and/or functional groups may not be decomposed and the first film 222 may not crystallize. In some embodiments, if the processing time is too long, such as longer than about 10 minutes, the manufacturing throughput may be adversely affected.

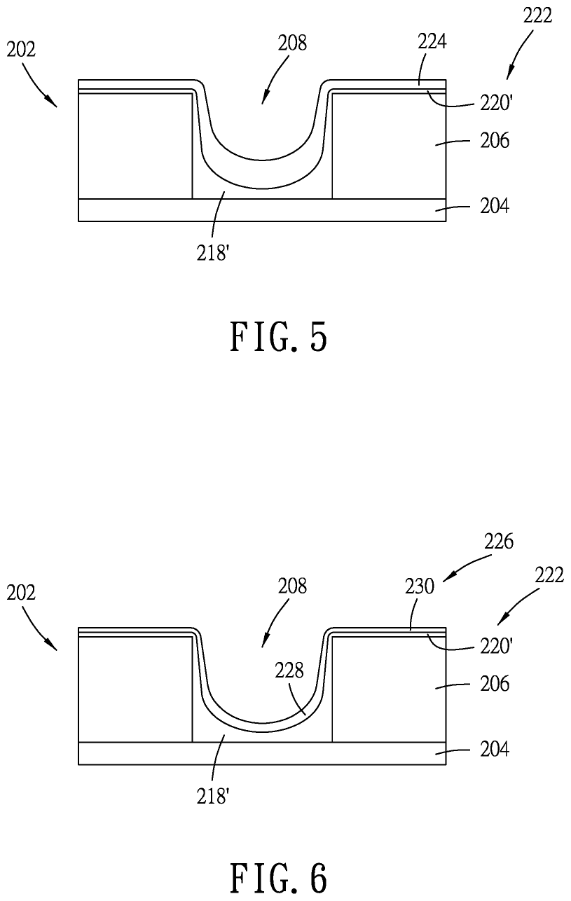

Referring to FIG. 1, in a step 106 of the method 100, a second coating is formed. Then, in a step 108 of the method 100, the second coating is turned into a second film. Referring to FIG. 5, in some embodiments, if the trench 208 is not completely filled by the first film 222, the second coating 224 is formed over the first film 222. In some embodiments, the materials and properties of the second coating 224 may be similar to those of the first coating 216 (see FIG. 3) with or without any suitable adjustments according to practical requirements, and are therefore not repeated for the sake of brevity. In some embodiments, the concentration of a second solution used for forming the second coating 224 may be equal to or higher than the concentration of the first solution used for forming the first coating 216. In some embodiments, the thickness of the second coating 224 may be similar to that of the first coating 216, or may be adjusted according to practical requirements. Then, referring to FIGS. 5 and 6, in some embodiments, the second coating 224 may be turned into the second film 226 by the abovementioned steps used for turning the first coating 216 (see FIG. 3) into the first film 222 (see FIG. 4) with or without any suitable adjustments according to practical requirements. In some embodiments, the second film 226 may have a second fill portion 228 that is formed in the trench 208 and that is formed on the first fill portion 218′ of the first film 222, and a second cover portion 230 that is formed over the feature 206 and that is formed on the first cover portion 220′ of the first film 222. In some embodiments, the second film 226 may be formed to be thicker than the first film 222, which may be due to the fact that the concentration of the second solution is higher than that of the first solution.

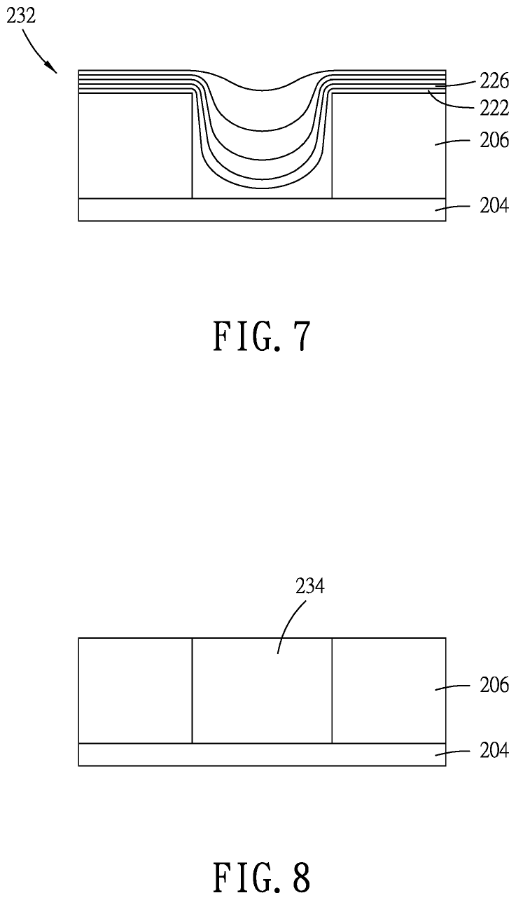

Referring to FIGS. 6 and 7, if the trench 208 is not completely filled by the first and second films 222, 226, the abovementioned steps of forming coatings and turning the coatings into films are repeated at least until the trench 208 is completely filled. As shown in FIG. 7, in some embodiments, the trench 208 (see FIG. 6) is completely filled by a filling structure 232 which includes the first film 222, the second film 226, and multiple layers of films formed by the abovementioned steps.

Referring to FIGS. 7 and 8, in some embodiments after the formation of the filling structure 232, a portion of the filling structure 232 formed over the feature 206 may be removed (e.g., by chemical mechanical planarization (CMP), dry etch, other suitable techniques, or any combination thereof) to obtain the filling feature 234 that fills the trench 208.

Referring to FIGS. 2 and 8, in some embodiments, the trench 208 may have a width (W) ranging from about 5 nm to about 1000 nm, but other ranges of values are also within the scope of this disclosure. In some embodiments, the trench 208 may have a depth (D) ranging from about 5 nm to about 1000 nm, but other ranges of values are also within the scope of this disclosure. In some embodiments, if the width (W) of the trench 208 is too small, such as smaller than about 5 nm, it is difficult to fill the trench 208 with the filling feature 234. In some embodiments, if the width (W) of the trench 208 is too large, such as larger than about 1000 nm, the trench 208 (i.e., the subsequently formed filling feature 234) may occupy too much space. In some embodiments, if the depth (D) of the trench 208 is smaller than about 5 nm, the trench 208 may be filled with the filling feature 234 by other techniques, such as ALD. In some embodiments, if the depth (D) of the trench 208 is too large, such as larger than about 1000 nm, it is difficult to fill the trench 208 with the filling feature 234 and carbon-containing residue may be trapped in the filling feature 234.

In some embodiments, the filling feature 234 made be made of the abovementioned HfO₂. In other embodiments, the filling feature 234 may be made of Al₂O₃, ZrO₂, ZnO₂, lead zirconate titanate (PZT), 2-sec-Butyl-4,5-dihydrothiazole (SBT, C₇H₁₃NS), other suitable materials, or any combination thereof. The solute may include AlCl₃, zirconium propoxide, zinc acetate, lead acetate, lead acetate trihydrate, zirconium n-propoxide, zirconium isopropoxide, titanium isopropoxide, other suitable materials, or any combination thereof. In some embodiments, the solute may include metal and ethyl acetoacetate, benzyl acetate, tetramethyl heptanedione (TMHD), etc. each being chelated or bonded to the metal.

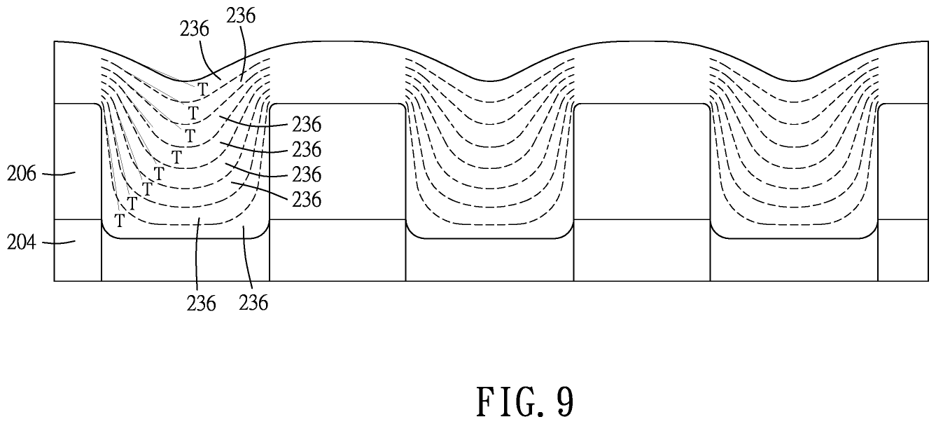

FIG. 9 is a schematic view showing multiple trenches that are filled by multiple films 236 that are made by the abovementioned steps. As shown in FIG. 9, sidewalls of the films 236 become less steep away from the substrate 204. That is, the slopes of a plurality of tangent lines (T) respectively intersecting sidewalls of the films 236 decrease proportional to distance away from the substrate 204 (i.e., the tangent lines (T) intersecting the sidewall of the topmost one of the films has the smallest slope). In some embodiments, the shapes of the films 236 are parabolic or rounded near the substrate 204. In some embodiments, the overall thickness of the films 236 may be determined by the dimensions of the trenches, the concentration of the solution used, the rotation rate of the substrate 204 when applying the solution, and other related factors. In some embodiments, the interfaces between the films 236 are indicated by dash lines for illustration purposes and may not be visible. In some embodiments, the films 236 are formed without any seams and/or voids.

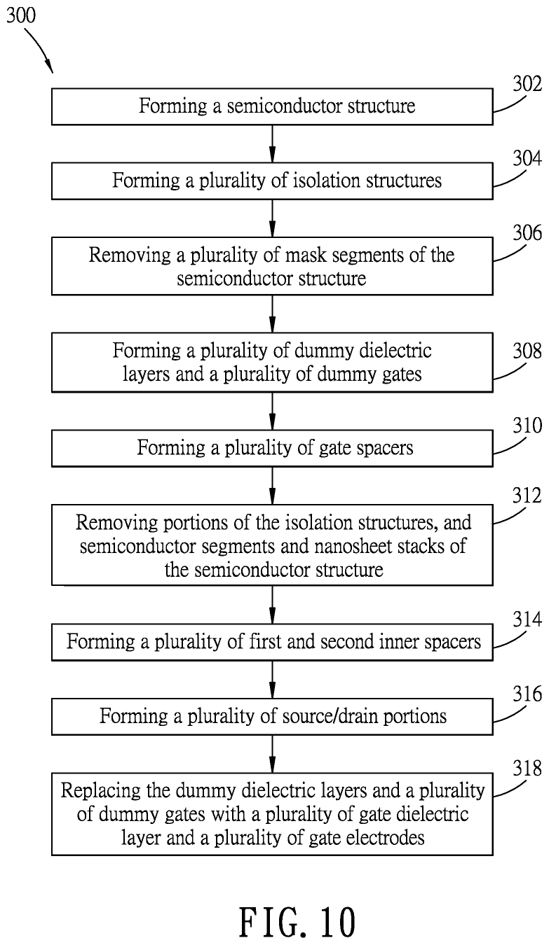

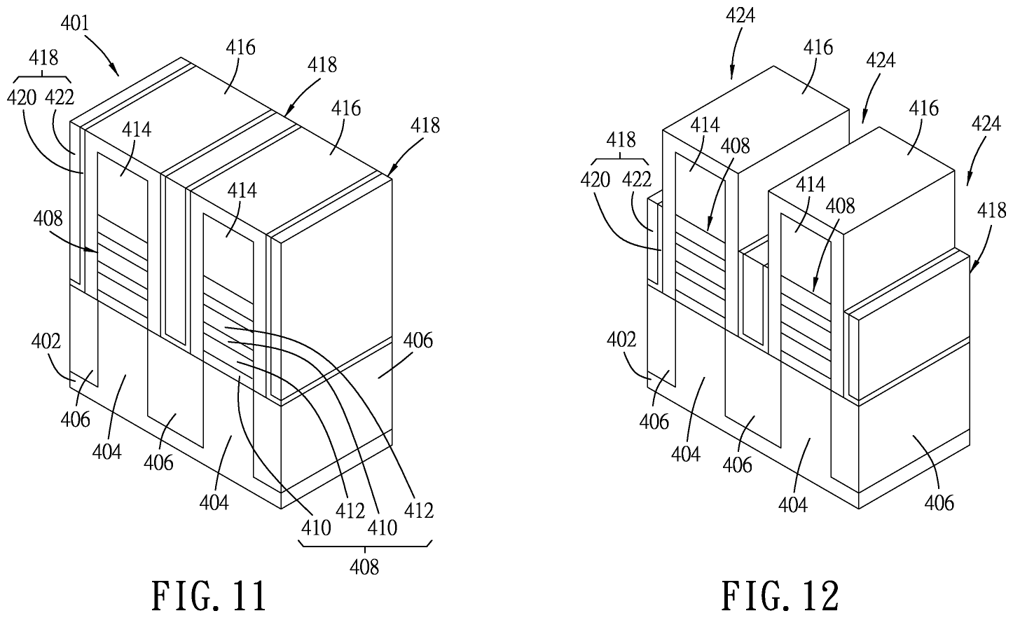

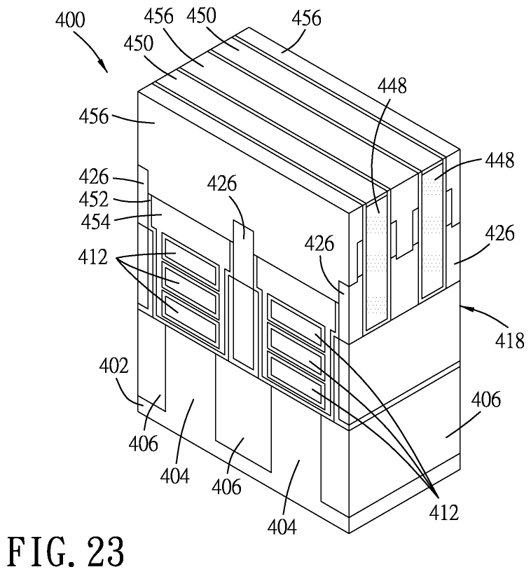

FIG. 10 illustrates a method 300 for forming a semiconductor device 400 (see FIG. 23) in accordance with some embodiments. FIGS. 11 to 23 are schematic views showing intermediate stages of the method 300 as depicted in FIG. 10. Additional steps which are not limited to those described in the method 300, can be provided before, after or during manufacturing of the semiconductor device 400, and some of the steps described herein may be replaced by other steps or be eliminated. Similarly, additional features may be present in the semiconductor device 400, and/or features present may be replaced or eliminated in additional embodiments.

Referring to FIG. 10, in a step 302 of the method 300, a semiconductor structure is formed. Referring to FIG. 11, in some embodiments, the semiconductor structure 401 includes a semiconductor substrate 402, a plurality of fins 404, a plurality of isolation features 406, a plurality of nanosheet stacks 408, a plurality of mask segments 414, a plurality of semiconductor layers 416, and a plurality of dielectric features 418. In some embodiments, the fins 404 may be disposed over the semiconductor substrate 402. The isolation features 406 may be disposed among the fins 404. The nanosheet stacks 408 may be respectively disposed over the fins 404. The mask segments 414 may be respectively formed over the nanosheet stacks 408. Each of the semiconductor layers 416 may surround a respective one of the nanosheet stacks 408 and a respective one of the mask segments 414. The dielectric features 418 may be disposed among the semiconductor layers 416. In some embodiments, each of the nanosheet stacks 408 may include a plurality of first and second nanosheets 410, 412 that are alternatingly disposed over the respective one of the fins 404. In some embodiments, each of the dielectric features 418 includes a dielectric body 422 and a dielectric film 420 surrounding the dielectric body 422.

In some embodiments, the semiconductor substrate 402 may be, for example, but not limited to, a silicon-on-insulator (SOI) substrate, a germanium-on-insulator (GOI) substrate, a bulk semiconductor substrate, or the like. The semiconductor substrate 402 may have multiple layers. The semiconductor substrate 402 may include, for example, elemental semiconductor materials, such as crystalline silicon, diamond, or germanium; compound semiconductor materials, such as silicon carbide, gallium arsenic, indium arsenide, gallium phosphide, indium arsenide, indium phosphide, or indium antimonide; alloy semiconductor materials, such as silicon germanium, silicon germanium carbide, gallium arsenic phosphide, aluminum gallium arsenide, or gallium indium phosphide; or combinations thereof. The semiconductor substrate 402 may be intrinsic or doped with a dopant or different dopants. Other materials suitable for the semiconductor substrate 402 are within the contemplated scope of the present disclosure. In some embodiments, the semiconductor substrate 402 is a bulk silicon substrate. In some embodiments, the fins 404 may be made by etching the semiconductor substrate 402 or may be formed over the semiconductor substrate 402 by epitaxial growth, other suitable techniques, or any combination thereof.

In some embodiments, the isolation features 406 may include an oxide-based material (e.g., silicon oxide), other suitable materials, or any combination thereof, and may be made by chemical vapor deposition (CVD), other suitable techniques, or any combination thereof.

In some embodiments, the first nanosheets 410 may be made of a material that has an etch selectivity and/or oxidation rate different from that of the second nanosheets 412. In some embodiments, the second nanosheets 412 may be made of the same material as the semiconductor substrate 402. In some embodiments, the first nanosheets 410 may be made of silicon germanium (SiGe), and the second nanosheets 412 may be made of silicon. Other materials suitable for the first and second nanosheets 410, 412 are within the contemplated scope of the present disclosure. In some embodiments, the first and second nanosheets 410, 412 may be made by CVD, atomic layer deposition (ALD), other suitable techniques, or any combination thereof.

In some embodiments, the mask segments 414 may be made by an oxide-based material (e.g., SiOₓ), a nitride-based material (e.g., SiN), other suitable materials, or any combination thereof, and may be made by CVD, ALD, physical vapor deposition (PVD), other suitable techniques, or any combination thereof.

In some embodiments, the semiconductor layers 416 and the second nanosheets 412 may be made of the same material. In some embodiments, the semiconductor layers 416 may be made of silicon germanium, other suitable materials, or any combination thereof. In some embodiments, the semiconductor layers 416 may be made by CVD, ALD, other suitable techniques, or any combination thereof.

In some embodiments, the dielectric film 420 and the dielectric body 422 of each of the dielectric features 418 may be made of different materials. In some embodiments, the dielectric film 420 of each of the dielectric features 418 may include a silicon-based material, such as silicon oxide, silicon nitride, silicon oxycarbide, other suitable materials, or any combination thereof. In some embodiments, the dielectric body 422 of each of the dielectric features 418 may include an oxide-based material, such as silicon oxide, other suitable materials, or any combination thereof. In some embodiments, the dielectric film 420 of each of the dielectric features 418 and the dielectric body 422 of each of the dielectric features 418 may be made by CVD, ALD, PVD, other suitable techniques, or any combination thereof.

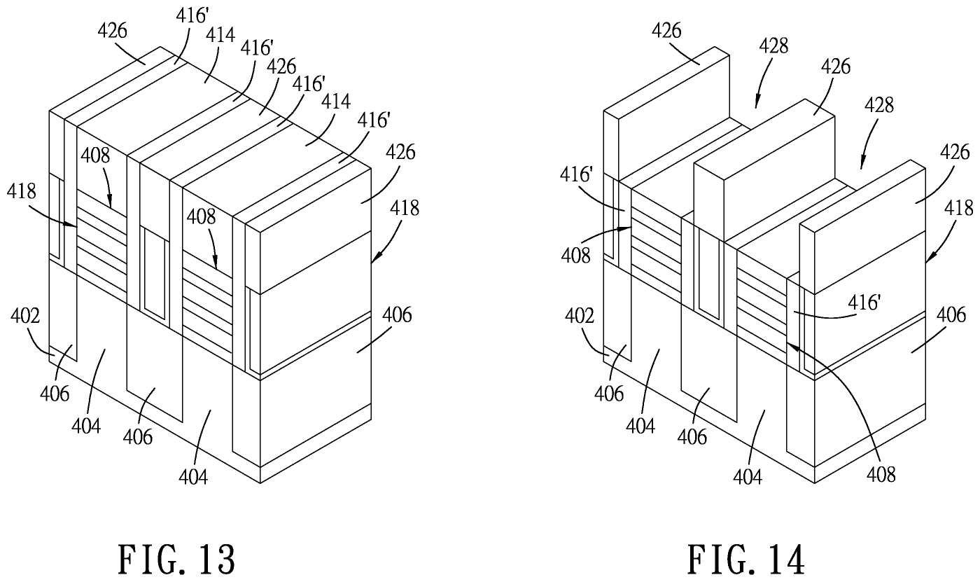

Referring to FIG. 10, in a step 304 of the method 300, a plurality of isolation structures are formed. Referring to FIG. 12, in some embodiments, top portions of the dielectric features 418 are removed to form a plurality of trenches 424, by dry etching, wet etching, other suitable techniques, or any combination thereof. Then, referring to FIG. 13, the isolation structures 426 are respectively formed in the trenches 424 (see FIG. 12), where the isolation structures 426 are similar to the filling feature 234 (see FIG. 8) and may be formed by the processes as described above. In some embodiments, during the formation of the isolation structures 426, top portions of the semiconductor layers 416 are removed to form a plurality of semiconductor segments 416′. In some embodiments, the isolation structures 426 may be made of HfO₂, Al₂O₃, ZrO₂, ZnO₂, PZT, SBT, other suitable materials, or any combination thereof.

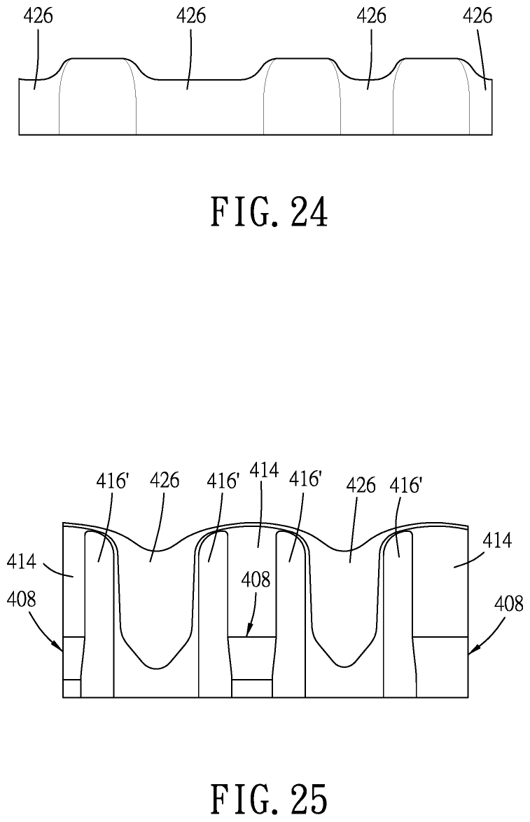

FIG. 24 shows a test structure having multiple trenches with the isolation structures 426 filled therein. The trenches have various dimensions.

Moreover, FIG. 25 is a schematic side view from FIG. 13, showing the isolation structures 426 being filled in the trenches 424 (see FIG. 12).

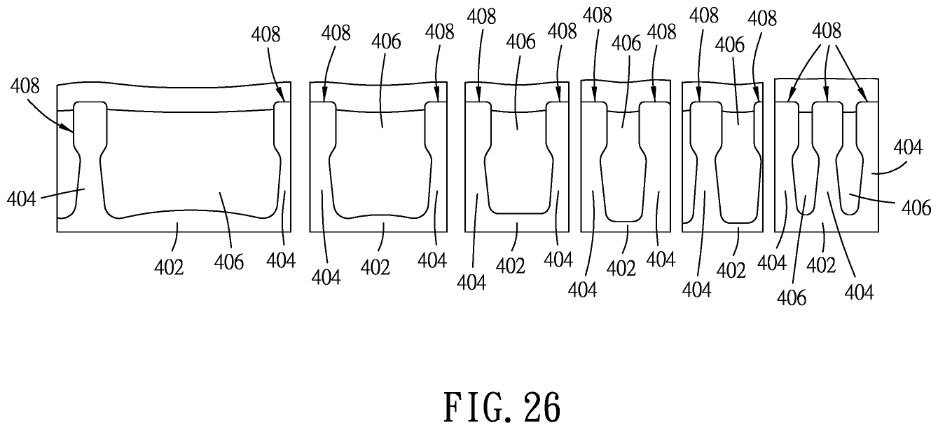

In addition, FIG. 26 shows multiple test structures, where a plurality of the isolation features 406 are formed in spaces of various dimensions between the fins 404. In the embodiments shown by FIG. 26, the isolation features 406 may be formed by the processes as described above for forming the filling feature 234 (see FIG. 8) and/or the isolation structures 426 (see FIG. 13).

Referring to FIG. 10, in a step 306 of the method 300, the mask segments of the semiconductor structure are removed. Referring to FIG. 14, in some embodiments, the mask segments 414 and upper portions of the semiconductor segments 416′ are removed, by dry etching, wet etching, other suitable techniques, or any combination thereof, to form a plurality of recesses 428.

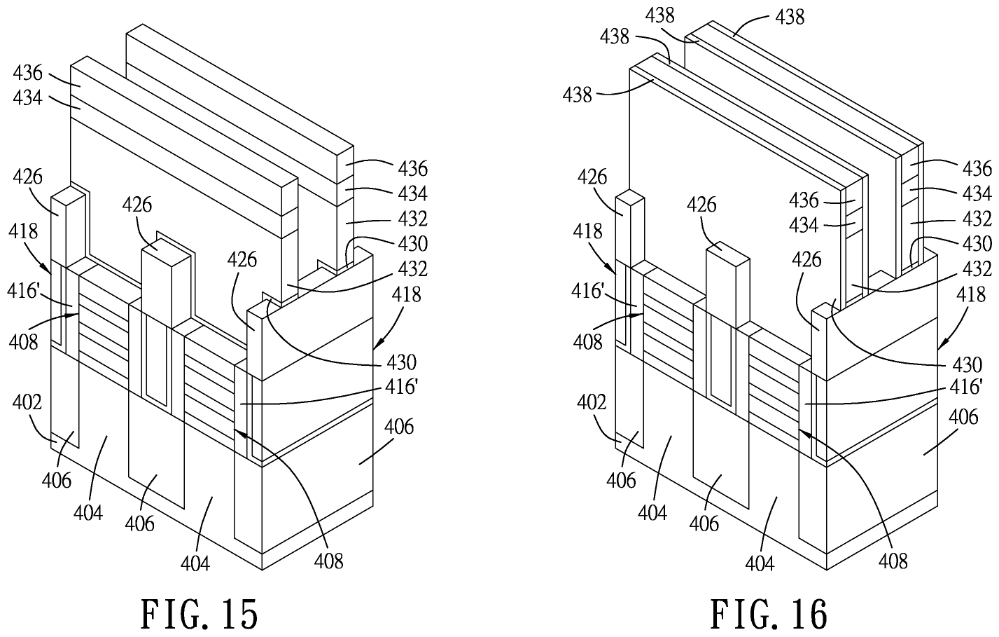

Referring to FIG. 10, in a step 308 of the method 300, a plurality of dummy dielectric layers and a plurality of dummy gates are formed. Referring to FIG. 15, in some embodiments, the dummy dielectric layers 430 are formed in the recesses 428 (see FIG. 14) and over the isolation structures 426. Then, in some embodiments, the dummy gates 432 are respectively formed over the dummy dielectric layers 430. In some embodiments, the dummy dielectric layers 430 and the dummy gates 432 may be formed by etching blanket materials (not shown) using a plurality of first hard masks 434 and a plurality of second hard masks 436 as etching masks, where the isolation structures 426 are unetched or only slightly etched during the etching of the blanket materials. Therefore, in some embodiments, the first hard masks 434 are respectively disposed over the dummy gates 432, and the second hard masks 436 are respectively disposed on the first hard masks 434. In some embodiments, each of the dummy dielectric layers 430 may include silicon oxide, other suitable materials, or any combination thereof. In some embodiments, each of the dummy gates 432 may include polycrystalline silicon, microcrystal silicon, amorphous silicon, other suitable materials, or any combination thereof. In some embodiments, each of the first and second hard masks 434, 436 may include silicon nitride, silicon oxide, silicon oxynitride, other suitable materials, or any combination thereof. In some embodiments, each of the dummy dielectric layers 430, the dummy gates 432, the first hard masks 434, and the second hard masks 436 may be made by ALD, CVD, PVD, other suitable techniques, or any combination thereof.

Referring to FIG. 10, in a step 310 of the method 300, a plurality of gate spacers are formed. Referring to FIG. 16, in some embodiments, the gate spacers 438 are formed, where each of the dummy dielectric layers 430, a respective one of the dummy gates 432, a respective one of the first hard masks 434, and a respective one of the second hard masks 436 are sandwiched between corresponding two of the gate spacers 438. In some embodiments, each of the gate spacers 438 may include silicon oxide, silicon nitride, silicon carbide, other suitable materials, or any combination thereof. In some embodiments, the gate spacers 438 may be made by CVD, PVD, other suitable techniques, or any combination thereof.

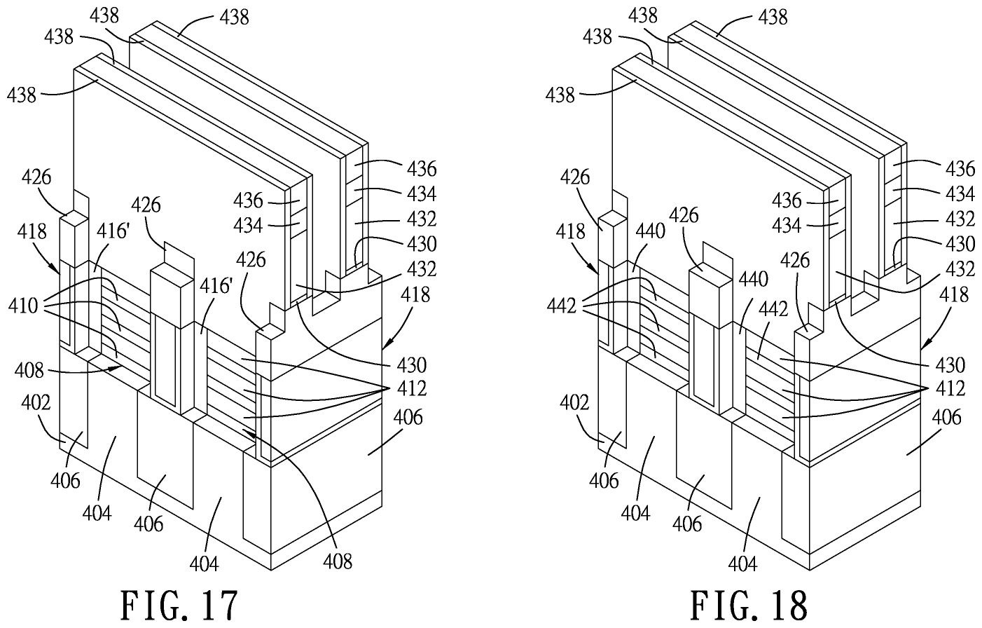

Referring to FIG. 10, in a step 312 of the method 300, portions of the isolation structures, the semiconductor segments and the nanosheet stacks are removed. Referring to FIG. 17, in some embodiments, portions of the isolation structures 426, the semiconductor segments 416′, and the first nanosheets 410 and the second nanosheets 412 of each of the nanosheet stacks 408 are removed, by dry etching, wet etching, other suitable techniques, or any combination thereof.

Referring to FIG. 10, in a step 314 of the method 300, a plurality of first inner spacers and a plurality of second inner spacers are formed. Referring to FIGS. 17 and 18, outer portions of the semiconductor segments 416′ may be replaced with the first inner spacers 440, and outer portions of the first nanosheets 410 may be replaced with the second inner spacers 442. In some embodiments, each of the first and second inner spacers 440, 442 may include a dielectric material which includes at least one of silicon (e.g., silicon oxide), carbon (e.g., silicon carbide), oxygen (e.g., silicon oxynitride), nitrogen (e.g., silicon nitride), fluorine, boron, other suitable materials, or any combination thereof, and may be made by ALD, CVD, PVD, other suitable techniques, or any combination thereof.

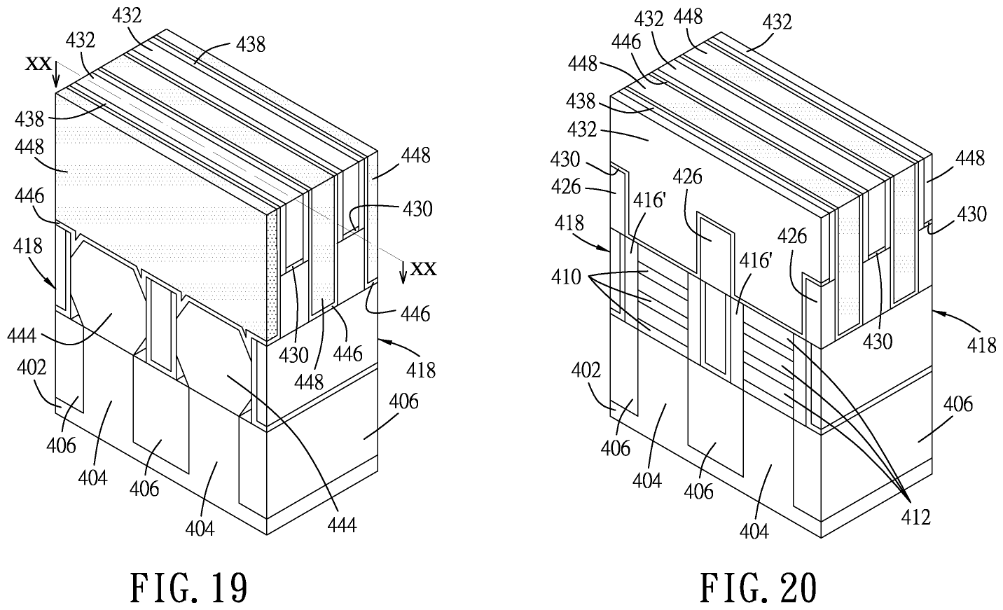

Referring to FIG. 10, in a step 316 of the method 300, a plurality of source/drain portions are formed. Referring to FIG. 19, in some embodiments, the source/drain portions 444 are formed, where each of the source/drain portions 444 is connected to corresponding ones of the second nanosheets 412. In some embodiments, each of the source/drain portions 444 may include silicon, silicon germanium, silicon carbide, germanium, other suitable materials, or any combination thereof. In some embodiments, the source/drain portions 444 may be made by epitaxial growth technique, other suitable techniques, or any combination thereof.

Referring to FIG. 19, in some embodiments, a plurality of contact etch stop layers 446 are formed. Each of the contact etch stop layers 446 may be formed on corresponding ones of the source/drain portions 444. Then, in some embodiments, a plurality of interlayer dielectric layers 448 may be respectively formed over the contact etch stop layers 446. In some embodiments, each of the contact etch stop layers 446 may include silicon oxide, silicon nitride, silicon carbide, other suitable material, or any combination thereof, and may be made by CVD, ALD, PVD, other suitable techniques, or any combination thereof. In some embodiments, each of the interlayer dielectric layers 448 may include silicon oxide, silicon nitride, silicon oxynitride, phosphosilicate glass (PSG), borophosphosilicate glass (BPSG) fluorosilicate glass (FSG), carbon-doped silicon oxide (e.g., SiCOH), polyimide, other suitable material, or any combination thereof. In some embodiments, during the formation of the contact etch stop layers 446 and the interlayer dielectric layers 448, the first and second hard masks 434, 436 and top portions of the dummy gates 432 may be removed.

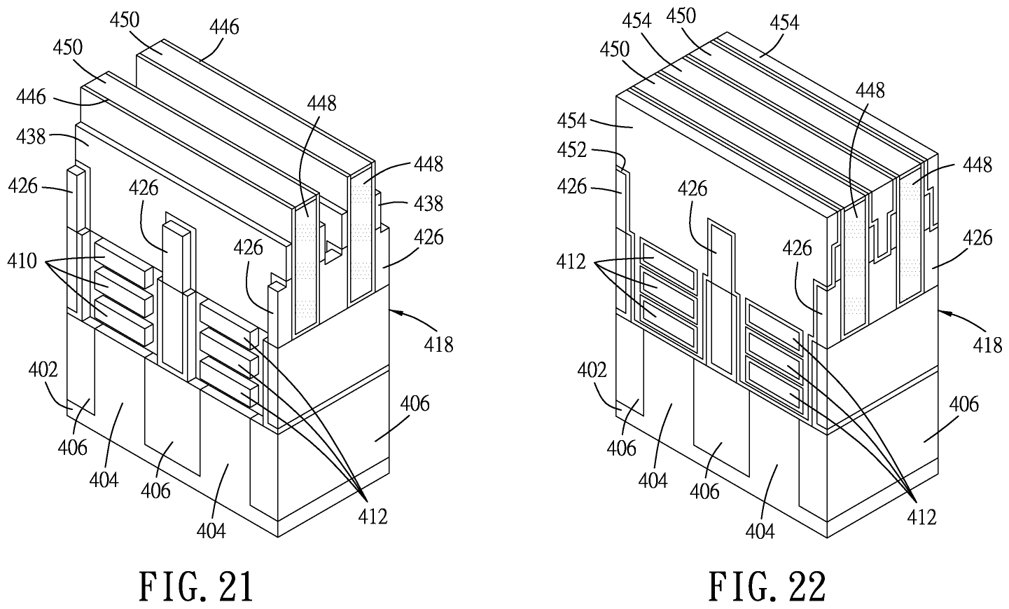

In some embodiments, FIG. 20 is a fragmentary perspective cross-sectional view taken along line XX-XX of FIG. 19 for ease of illustrating subsequent processing steps. Referring to FIG. 10, in a step 318 of the method 300, the dummy dielectric layers and the dummy gates are replaced with a plurality of gate dielectric layers and a plurality of gate electrodes. Referring to FIG. 21, in some embodiments, the dummy gates 432 and the dummy dielectric layers 430 may be removed, and top portions of the gate spacers 438 may be removed, by dry etching, wet etching, other suitable techniques, or any combination thereof, where the isolation structures 426 are unetched or only slightly etched. In some embodiments, portions of the isolation structures 426 may be removed by dry etching, wet etching, other suitable techniques, or any combination thereof. In some embodiments, the first nanosheets 410 and the semiconductor segments 416′ may be removed by dry etching, wet etching, other suitable techniques, or any combination thereof. Then, referring to FIG. 22, in some embodiments, the gate dielectric layers 452 are formed to surround the second nanosheets 412, and the gate electrodes 454 are formed over the gate dielectric layers 452. In some embodiments, the gate dielectric layers 452 may include a high-k dielectric material, such as Hf-based materials, Zr-based materials, Al-based materials, Ti-based materials, Ba-based materials, nitrides, other suitable materials, or any combination thereof. In some embodiments, the gate dielectric layers 452 may be formed by ALD, CVD, PVD, other suitable techniques, or any combination thereof. In some embodiments, the gate electrodes 454 may include metal (e.g., Cu, Al, Ti, Ta, Co, W, etc.), polysilicon, metal-containing nitride (e.g., TaN, etc.), metal-containing silicide (e.g., NiSi, etc.), metal-containing carbide (e.g., TaC, etc.), other suitable materials, or any combination thereof. In some embodiments, the gate electrodes 454 may be made by ALD, CVD, PVD, plating, other suitable techniques, or any combination thereof.

Referring to FIG. 23, in some embodiments, top portions of the gate dielectric layers 452 and the gate electrodes 454 may be removed, wherein the isolation structures 426 are unetched or only slightly etched. Then, in some embodiments, a plurality of mask structures 456 (may be referred to as self-aligned contact (SAC) in some embodiments) are formed, thereby obtaining the semiconductor device 400. In some embodiments, the mask structures 456 may include silicon oxide, silicon nitride, silicon carbide, boron nitride, boron carbide, other suitable materials, or any combination thereof.

In some embodiments, during the formation of the semiconductor device 400, there may be a wet clean process after each of the etching processes. The isolation structures 426 are unetched or only slightly etched during the wet clean processes.

The embodiments of the present disclosure have some advantageous features. Since the solution of this disclosure is diluted, and is applied in multiple coating-and-baking steps, thereby minimizing shrinkage of the films thus formed (e.g., the first and second films 222, 226), and alleviating the formation of seams/voids in the filling feature 234. In addition, the ligand and/or functional groups can be easily removed with the multiple coating-and-baking steps, which also improves film quality and alleviates the formation of seams/voids. Therefore, a high shrinkage material (e.g., a material that has a thickness shrinkage greater than about 30%) can be used for filling trenches. The method can also be used for forming films with superior thermal stability, etch resistance, which can be used for filling trenches in various semiconductor structures including field-effect transistors, capacitors, ferroelectric devices, etc.

In accordance with some embodiments of the present disclosure, a method for filling a trench in a semiconductor device includes: applying a first solution to a semiconductor structure of a semiconductor device to form a first coating over the semiconductor structure, the semiconductor structure including a feature and the trench formed in the feature, the first coating being formed in the trench and over the feature, the first solution containing a metal-containing solute; heating the first coating in a multi-step procedure to turn the first coating into a first film, the multi-step procedure including heating the first coating at a first temperature, followed by heating the first coating at a second temperature not lower than the first temperature; applying a second solution onto the first film to form a second coating over the first film, the second solution containing the metal-containing solute; and heating the second coating in a multi-step procedure to turn the second coating into a second film, the multi-step procedure including heating the second coating at a third temperature, followed by heating the second coating at a fourth temperature not lower than the third temperature.

In accordance with some embodiments of the present disclosure, in the step of applying the first solution, the first solution has a concentration ranging from about mol % to about 20 mol %.

In accordance with some embodiments of the present disclosure, in the step of applying the second solution, the second solution has a concentration higher than that of the first solution.

In accordance with some embodiments of the present disclosure, in the step of heating the first coating, the first temperature ranges from about 100° C. to about 170° C., and the second temperature ranges from about 170° C. to about 300° C.

In accordance with some embodiments of the present disclosure, the multi-step procedure for heating the first coating further includes heating the first coating at a temperature ranging from about 300° C. to about 550° C.

In accordance with some embodiments of the present disclosure, the multi-step procedure for heating the first coating further includes, after the first coating is heated at about 300° C. to about 550° C., heating the first coating at about 550° C. to about 650° C.

In accordance with some embodiments of the present disclosure, the method further includes exposing the first coating to a UV light after heating during the multi-step procedure for heating the first coating.

In accordance with some embodiments of the present disclosure, the UV light has a wavelength ranging from about 120 nm to about 220 nm.

In accordance with some embodiments of the present disclosure, the method further includes, after the step of heating the first coating to turn the first coating into the first film, exposing the first film to a UV light.

In accordance with some embodiments of the present disclosure, the UV light has a wavelength ranging from about 120 nm to about 220 nm.

In accordance with some embodiments of the present disclosure, in the step of applying the first solution to the semiconductor structure, the first coating has a fill portion in the trench and a cover portion over the feature, the fill portion having a thickness (T1) measured at a center of the trench, the cover portion having a thickness (T2), T2 being smaller than about one tenth of T1.

In accordance with some embodiments of the present disclosure, in the step of heating the first coating, the first film has a first fill portion that is formed in the trench 208, and that has a thickness (T1′), T1′ being greater than about seven tenth of T1.

In accordance with some embodiments of the present disclosure, in the step of applying the first solution to the semiconductor structure, the metal-containing solute is an ionic compound or a coordination complex.

In accordance with some embodiments of the present disclosure, the metal-containing solute includes a metal coordination complex.

In accordance with some embodiments of the present disclosure, in the step of heating the second coating, the second film is formed to be thicker than the first film.

In accordance with some embodiments of the present disclosure, a method for filling a trench includes: applying a first solution to a structure to form a first coating over the structure, the structure including a feature and the trench formed in the feature, the first coating being formed in the trench and over the feature, the first solution containing a metal-containing solute; heating the first coating in an environment with increasing temperature, thereby turning the first coating into a first film; applying a second solution onto the first film to form a second coating over the first film, the second solution containing the metal-containing solute and having a concentration higher than that of the first solution; and heating the second coating in an environment with increasing temperature, thereby turning the second coating into a second film (226).

In accordance with some embodiments of the present disclosure, in the step of heating the first coating, the first coating is heated at a temperature ranging from about 100° C. to about 170° C., and then heated at a temperature ranging from about 170° C. to about 300° C. In the step of heating the second coating, the second coating is heated at a temperature ranging from about 100° C. to about 170° C., and then heated at a temperature ranging from about 170° C. to about 300° C.

In accordance with some embodiments of the present disclosure, after the first coating is heated at the temperature ranging from about 170° C. to about 300° C., the first coating is further heated at a temperature not lower than about 300° C. After the second coating is heated at the temperature ranging from about 170° C. to about 300° C., the second coating is further heated to a temperature not lower than about 300° C.

In accordance with some embodiments of the present disclosure, a method for forming a semiconductor device includes: forming a semiconductor structure including a semiconductor substrate, a plurality of nanosheet stacks disposed over the semiconductor substrate, a plurality of mask segments respectively disposed over the nanosheet stacks, and a plurality of trenches disposed among the mask segments; applying a solution to the semiconductor structure to form a coating in the trenches and over the mask segments; heating the coating in a multi-step procedure to turn the coating into a film; repeating the steps of applying the solution and heating the coating until the trenches are filled; removing the mask segments; forming a plurality of dummy dielectric layers over the semiconductor structure; and forming a plurality of dummy gates respectively over the dummy dielectric layers.

In accordance with some embodiments of the present disclosure, the multi-step procedure includes heating the coating at a first temperature, followed by heating the coating at a second temperature not lower than the first temperature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for filling a trench in a semiconductor device, comprising:
applying a first solution to a semiconductor structure of a semiconductor device to form a first coating over the semiconductor structure, the semiconductor structure including a feature and a trench formed in the feature, the first coating being formed in the trench and over the feature, the first solution containing a metal-containing solute;
heating the first coating in a multi-step procedure to turn the first coating into a first film, the multi-step procedure including heating the first coating at a first temperature, followed by heating the first coating at a second temperature not lower than the first temperature;
applying a second solution onto the first film to form a second coating over the first film, the second solution containing the metal-containing solute; and
heating the second coating in a multi-step procedure to turn the second coating into a second film, the multi-step procedure including heating the second coating at a third temperature, followed by heating the second coating at a fourth temperature not lower than the third temperature.

2. The method as claimed in claim 1, wherein, in the step of applying the first solution, the first solution has a concentration ranging from about 0.00001 mol % to about 20 mol %.

3. The method as claimed in claim 1, wherein, in the step of applying the second solution, the second solution has a concentration higher than that of the first solution.

4. The method as claimed in claim 1, wherein, in the step of heating the first coating, the first temperature ranges from about 100° C. to about 170° C., and the second temperature ranges from about 170° C. to about 300° C.

5. The method as claimed in claim 4, wherein, the multi-step procedure for heating the first coating further includes heating the first coating at a temperature ranging from about 300° C. to about 550° C.

6. The method as claimed in claim 5, wherein the multi-step procedure for heating the first coating further includes, after the first coating is heated at about 300° C. to about 550° C., heating the first coating at about 550° C. to about 650° C.

7. The method as claimed in claim 1, further comprising exposing the first coating to a UV light after heating during the multi-step procedure for heating the first coating.

8. The method as claimed in claim 7, wherein the UV light has a wavelength ranging from about 120 nm to about 220 nm.

9. The method as claimed in claim 1, further comprising, after the step of heating the first coating to turn the first coating into the first film, exposing the first film to a UV light.

10. The method as claimed in claim 9, wherein the UV light has a wavelength ranging from about 120 nm to about 220 nm.

11. The method as claimed in claim 1, wherein, in the step of applying the first solution to the semiconductor structure, the first coating has a fill portion in the trench and a cover portion over the feature, the fill portion having a thickness (T1) measured at a center of the trench, the cover portion having a thickness (T2), T2 being smaller than about one tenth of T1.

12. The method as claimed in claim 11, wherein, in the step of heating the first coating, the first film has a first fill portion that is formed in the trench, and that has a thickness (T1′), T1′ being greater than about seven tenth of T1.

13. The method as claimed in claim 1, wherein, in the step of applying the first solution to the semiconductor structure, the metal-containing solute is an ionic compound or a coordination complex.

14. The method as claimed in claim 1, wherein the metal-containing solute includes a metal coordination complex.

15. The method as claimed in claim 1, wherein, in the step of heating the second coating, the second film is formed to be thicker than the first film.

16. A method for filling a trench, comprising:
applying a first solution to a structure to form a first coating over the structure, the structure including a feature and the trench formed in the feature, the first coating being formed in the trench and over the feature, the first solution containing a metal-containing solute;
heating the first coating in an environment with increasing temperature, thereby turning the first coating into a first film;
applying a second solution onto the first film to form a second coating over the first film, the second solution containing the metal-containing solute and having a concentration higher than that of the first solution; and
heating the second coating in an environment with increasing temperature, thereby turning the second coating into a second film.

17. The method as claimed in claim 16, wherein:
in the step of heating the first coating, the first coating is heated at a temperature ranging from about 100° C. to about 170° C., and then heated at a temperature ranging from about 170° C. to about 300° C.; and
in the step of heating the second coating, the second coating is heated at a temperature ranging from about 100° C. to about 170° C., and then heated at a temperature ranging from about 170° C. to about 300° C.

18. The method as claimed in claim 17, wherein:
after the first coating is heated at the temperature ranging from about 170° C. to about 300° C., the first coating is further heated at a temperature not lower than about 300° C.; and
after the second coating is heated at the temperature ranging from about 170° C. to about 300° C., the second coating is further heated to a temperature not lower than about 300° C.

19. A method for forming a semiconductor device, comprising:
forming a semiconductor structure including a semiconductor substrate, a plurality of nanosheet stacks disposed over the semiconductor substrate, a plurality of mask segments respectively disposed over the nanosheet stacks, and a plurality of trenches disposed among the mask segments;
applying a solution to the semiconductor structure to form a coating in the trenches and over the mask segments;
heating the coating in a multi-step procedure to turn the coating into a film;
repeating the steps of applying the solution and heating the coating until the trenches are filled;
removing the mask segments;
forming a plurality of dummy dielectric layers over the semiconductor structure; and
forming a plurality of dummy gates respectively over the dummy dielectric layers.

20. The method as claimed in claim 19, wherein the multi-step procedure includes heating the coating at a first temperature, followed by heating the coating at a second temperature not lower than the first temperature.
